(19) United States
(12) Patent Application Publication
(10) Pub. No.: US 2009/0009934 A1
(43) Pub. Date: Jan. 8, 2009

(54) HINGE ASSEMBLY FOR FOLDABLE ELECTRONIC DEVICES

(75) Inventors: CHIA-HUA CHEN, Shindian (TW); CHAO DUAN, Shenzhen (CN)

Correspondence Address: PCE INDUSTRY, INC.;ATT. CHENG-JU CHIANG, 458 E. LAMBERT ROAD, FULLERTON, CA, 92835, US

(73) Assignees: SHENZHEN FUTAIHONG PRECISION INDUSTRY CO., LTD., ShenZhen City (CN); SUTECH TRADING LIMITED, Tortola (VG)

(21) Appl. No.: 11/946,434

(22) Filed: Nov. 28, 2007

(30) Foreign Application Priority Data
Jul. 6, 2007 (CN) 200710075835.3

(51) Int. Cl. H05K 7/16; E05D 11/10

(52) U.S. Cl. 361/679; 16/319

(57) ABSTRACT

A hinge assembly (10) includes a shaft (12) and a follower (16), wherein one of the shaft and the follower define a thread (122), the other of the shaft and the follower disposes at least one resisting portion (166), and the shaft and the follower slide and rotate relative to each other. The hinge assembly is that it has only three main components, and occupies a relatively small volume.

### BACKGROUND OF THE INVENTION

1. Field of the Invention

The present invention relates to hinge assemblies and, particularly, to a hinge assembly for foldable electronic devices such as mobile phones, portable computers, and so on.

2. Description of Related Art

At present, perhaps the most popular portable electronic device in the marketplace is the foldable mobile phone, which generally includes a cover section and a body section. The cover section and the body section are rotatably interconnected through a hinge assembly, for switching the telephone between an in-use position and a closed position.

One kind of hinge assembly employs a cam and a follower, which makes the cover section fold outward from the body section and then hold in an open position. The hinge assembly typically includes a cam having a concave portion, a follower having a convex portion, a shaft having a fixing end, and a spring. The cam and the follower are placed around the shaft. The spring resists the follower to make the concave portion tightly contact with the convex portion. The cover section rotates about the body section of the mobile phone by overcoming the force of the spring, thus making the concave portion rotate about the convex portion.

However, although the hinge assembly may achieve the opening and closing of the foldable electronic device, the manufacture of the cam and the follower is complicated owing to the concave portion and convex portion. Furthermore, tip portions of the concave portion and the convex portion are sharp and easily abraded. In addition, during the process of opening and closing of the cover section of the foldable electronic device, one of the cam and the follower is quickly rotated under the elastic force of the spring, which produces a large impact on the cover section. The damage caused by this may also eventually lead to premature malfunction or failure of the foldable electronic device.

Therefore, a new hinge assembly is desired in order to overcome the above-described shortcoming.

### SUMMARY OF THE INVENTION

One present embodiment of a hinge assembly includes a shaft and a follower, wherein one of the shaft and the follower define a thread, the other of the shaft and the follower dispose at least one resisting portion, and the shaft and the follower slide and rotate relative to each other.

Other advantages and novel features will become more apparent from the following detailed description when taken in conjunction with the accompanying drawings.

### BRIEF DESCRIPTION OF THE DRAWINGS

Many aspects of the present hinge assembly can be better understood with reference to the following drawings. The components in the drawings are not necessarily drawn to scale, the emphasis instead being placed upon clearly illustrating the principles of the present hinge assembly. Moreover, in the drawings, like reference numerals designate corresponding parts throughout the several views.

FIG. 1 is an exploded, isometric view of a first embodiment of the hinge assembly;

FIG. 2 is a front view of a follower of the hinge assembly shown in FIG. 1;

FIG. 3 is an assembled view of the hinge assembly shown in FIG. 1;

FIG. 4 is an exploded, isometric view of the first embodiment of the hinge assembly shown in FIG. 1, as used in a mobile phone;

FIG. 5 is an assembled view of the present hinge assembly of FIG. 1, applied in the portable electronic device;

FIG. 6 is an exploded, isometric view of a second embodiment of the hinge assembly;

FIG. 7 is an assembled view of the second embodiment of the hinge assembly shown in FIG. 6;

FIG. 8 is an exploded, isometric view of a third embodiment of the hinge assembly;

FIG. 9 is an exploded, isometric view of a forth embodiment of the hinge assembly;

FIG. 10 is a front view of a follower of the hinge assembly shown in FIG. 9;

FIG. 11 is an assembled view of the hinge assembly shown in FIG. 10; and

FIG. 12 is an exploded, isometric view of the hinge assembly shown in FIG. 9, applied in a mobile phone.

### DETAILED DESCRIPTION OF THE EMBODIMENTS

The present hinge assembly is suitable for a foldable electronic device such as a flip type mobile phone, for pivotably coupling a cover section and a body section. It is to be understood, however, that the present hinge assembly could be advantageously used in other environments (e.g. cabinet doors). As such, although proving particularly advantageous when used in foldable electronic devices, the present hinge assembly should not be considered limited in scope solely to them.

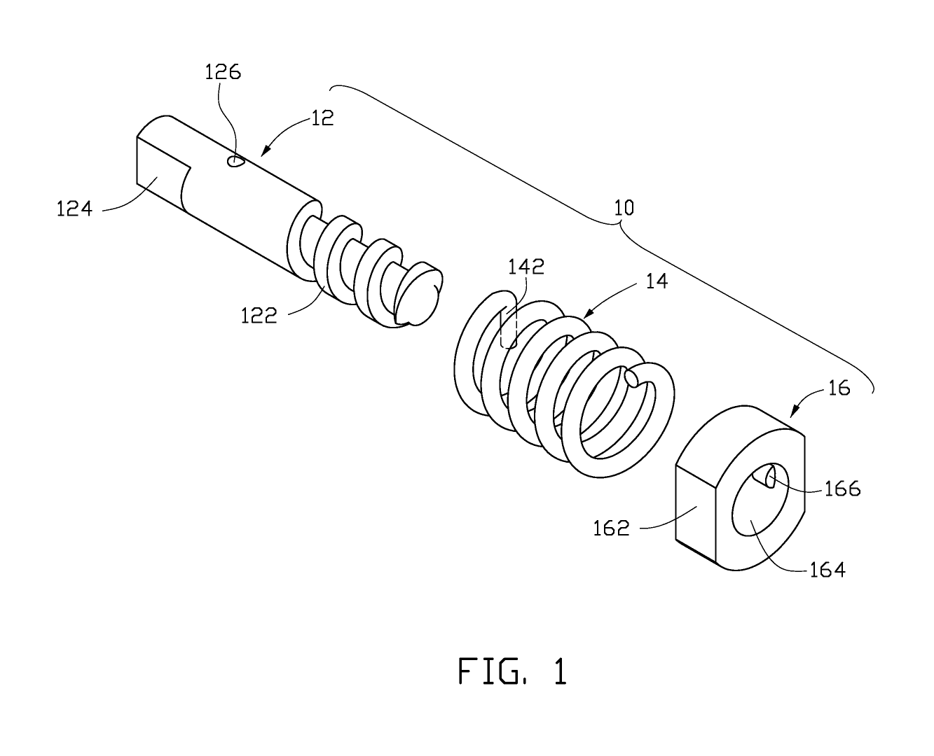

Referring now to FIG. 1, a hinge assembly 10 according to a first embodiment is provided. The hinge assembly 10 includes a shaft 12, a spring 14, and a follower 16.

The shaft 12 is substantially cylindrical. One end of the shaft 12 defines a screw portion 122 at an outer peripheral surface thereof, and the other end of the shaft 12 forms a deformed portion 124 functioning as a securing portion. The screw portion 122 is a singe thread, which is a raised helical or spiral rib/ridge on the shaft. The shaft 12 defines a pin hole 126 at the outer peripheral surface thereof adjacent to the deformed portion 124.

The spring 14 is preferably helical and metallic. The spring 14 has an inner diameter larger than a diameter of the shaft 12. Thus, the spring 14 can be placed around the shaft 12. One end of the spring 14 extends radially to a fixing end 142. A diameter of the fixing end 142 is same as that of the pin hole 126 of the shaft 12, therefore the fixing end 142 can be inserted into the pin hole 126 for attaching the spring 14 to the shaft 12.

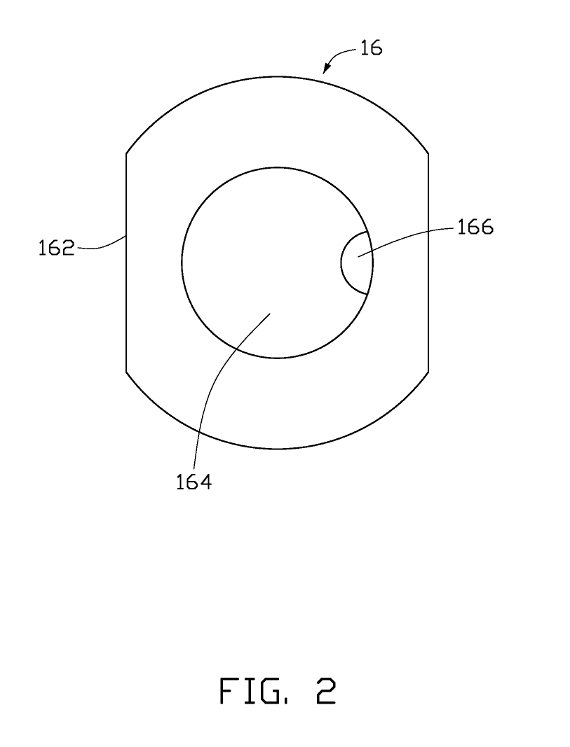

Referring now to FIG. 2, the follower 16 is generally cylindrical in shape and defines a through hole 164 therein. The follower 16 includes two opposite planar surfaces 162 at an outer peripheral wall thereof. A projection 166 is formed on an inner peripheral wall of the follower 16 and the projection 166 corresponds to the screw portion 122 of the shaft 12. The projection 166 is substantially a half-cylinder, and includes an arcuate surface towards a center of the through hole 164.

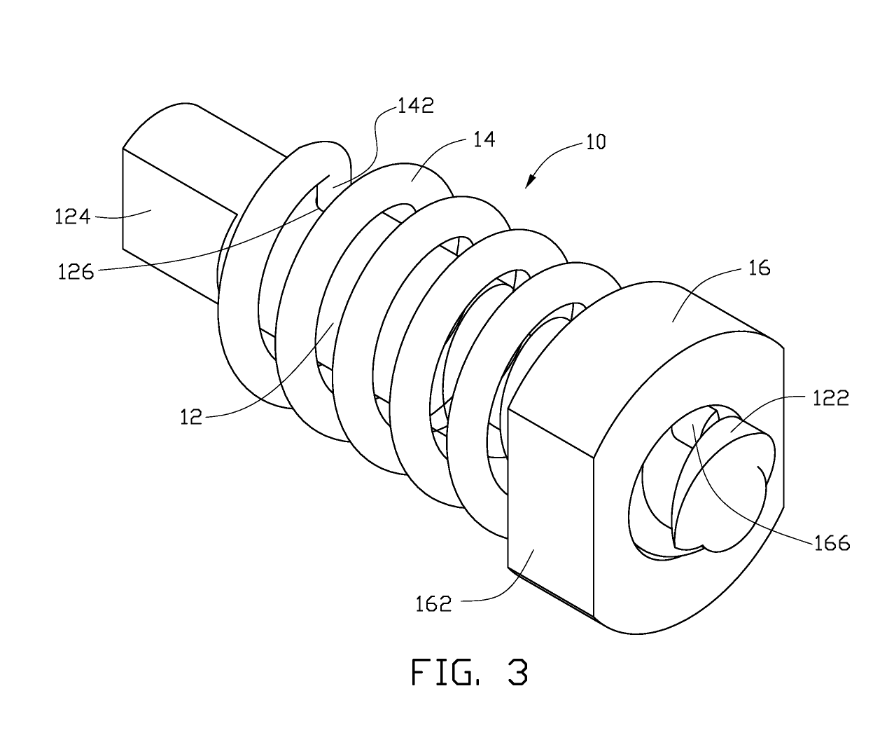

Referring to FIG. 3, in assembly, firstly, the spring 14 is placed around the shaft 12, and the fixing end 142 is inserted into the pin hole 126 of the shaft 12 for fixing one end of the spring 14 to the shaft 12. Then, the shaft 12 passes through the through hole 164 of the follower 16 and the projection 166 engages into the screw portion 122 of the shaft 12. A thread lead angle of the screw portion 122 is larger than a friction angle thereof so that when an axial force of the spring 14 applied on the follower 16, the projection 166 may overcome the frictional force of the screw portion 122 to slide and rotate along the screw portion 122.

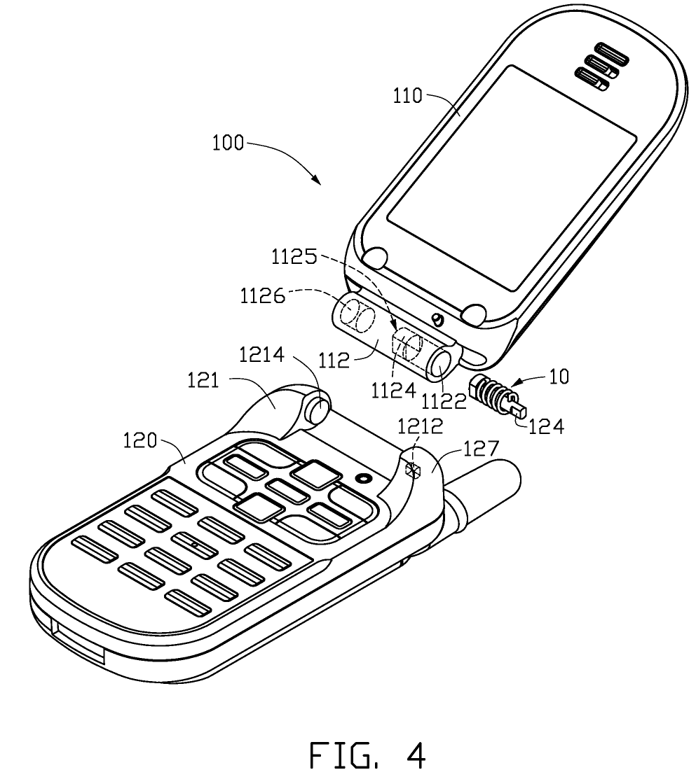

When the hinge assembly 10 is applied in a mobile phone including a cover section and a body section, the shaft 12 and the follower 16 respectively connect with the cover section and the body section. Referring to FIG. 4, the mobile phone 100 includes a cover section 110 and a body section 120. The cover section 110 has a connecting portion 112 at one end thereof. The connecting portion 112 defines a receiving cavity 1122 and a first reverse rotating groove 1124 at one end thereof. The receiving cavity 1122 is adjacent to the first reverse rotating groove 1124. The connecting portion 112 has a bottom wall 1125 at one side of the first reverse rotating groove 1124. The connecting portion 112 defines a cylindrical groove 1126 at the other end on the opposite side of the receiving cavity 1122. The body section 120 has two opposite engaging portion 121, 127 formed at one side thereof for connecting to the connection portion 112 of the cover section 110. The engaging portion 121 defines a second reverse rotating groove 1212 at one side thereof toward the engaging portion 127. The engaging portion 127 axially extends a connecting shaft 1214 at one side thereof toward the second reverse rotating groove 1212.

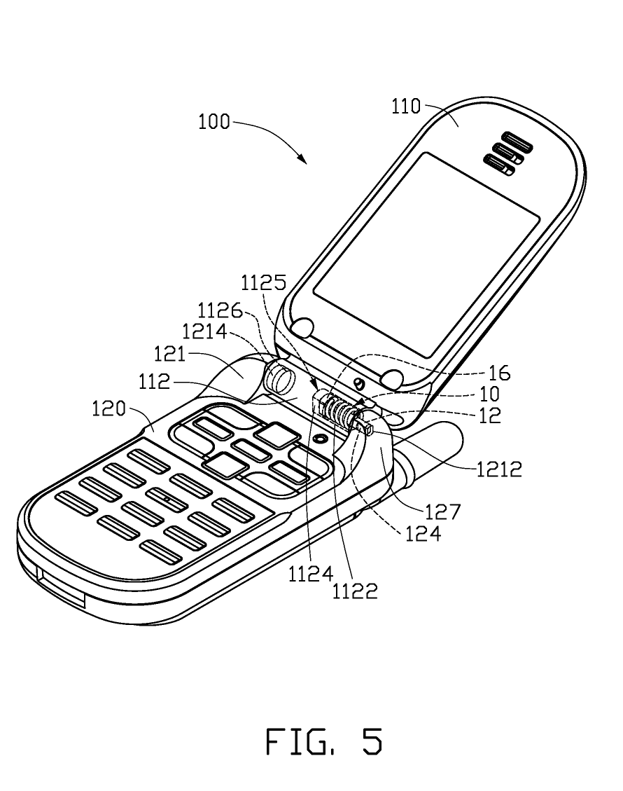

Referring to FIG. 5, the hinge assembly 10 is assembled in the mobile phone 100. One end of the assembled hinge assembly 10 with the follower 16 is inserted into the receiving cavity 1122. The follower 16 is engaged in the first reverse rotating groove 1124 via the planar surfaces 162. The deformed portion 124 of the shaft 12 reveals out of the receiving cavity 1122.

After that, the connecting portion 112 of the cover section 110 is disposed between the two engaging portions 121, 127. The connecting shaft 1214 of the body section 120 rotatably engages in the cylindrical groove 1126, and the deformed portion 124 engages in the second reverse rotating groove 1212. The cover section 110 can rotate relative to the body section 120 between an open position and a closed position via the hinge assembly 10.

In an initial state, the cover section 110 is closed relative to the body section 120. The follower 16 cannot rotate relative to the cover section 110, but can slide relative to the cover section 110. The shaft 12 cannot rotate relative to the body section 120. One end of the spring 14 is fixed in the shaft 12, and the other end of the spring 14 resists the follower 16. The spring 14 is in a compressed state, and the follower 16 has the tendency to rotate relative to the shaft 12 under an axial force provided by the spring 14. However, the cover section 110 or the follower 16 is locked in the body section 120 by a latch mechanism (not shown) so that the cover section 110 cannot rotate relative to the body section 120.

When opening the cover section 110, the latch mechanism is unlocked, and the cover section 110 and the follower 16 are released from the limitation of the latch mechanism. Then, the spring 14 pushes the follower 16 to make the follower 16 rotate and slide axially along the shaft 12 under the continuous engagement between the projection 166 and the screw portion 122. As the follower 16 slides, the spring 14 is relaxed. The follower 16 does not stop to slide until it reaches the bottom wall 1125 inside the first reverse rotating groove 1124. Thus, the cover section 110 is automatically opened relative to the body section 120 when the latch mechanism is unlocked.

When the cover section 110 rotates from the open position to the closed position, the follower 16 is rotated relative to the shaft 12. Simultaneously, the follower 16 moves axially along the shaft 12 and compresses the spring 14. The cover section 110 rotates continuously until the cover section 110 is locked on the body section 120 by the latch mechanism. When the cover section 110 is locked on the body section 120 by the latch mechanism, the spring 14 accumulates a predetermined elastic energy. At that time, the cover section 110 is completely closed relative to the body section 120. When the cover section 110 is opened, as long as the latch mechanism is unlocked, the cover section 110 automatically resumes to an open state under the role of the elastic energy of the spring 14.

In the embodiment described above, one of the advantage of the hinge assembly 10 is that it only has three main components, and occupies a relatively small volume. Accordingly, the occupied space of the hinge assembly 10 required in an application such as the mobile phone 100 is reduced. In addition, the engagement of the screw portion 122 and the projection 166 of the follower 16 can dampen the opening of the cover section 110, so that the cover section 110 is protected from damage, thus prolonging the lifetime of the mobile phone 100.

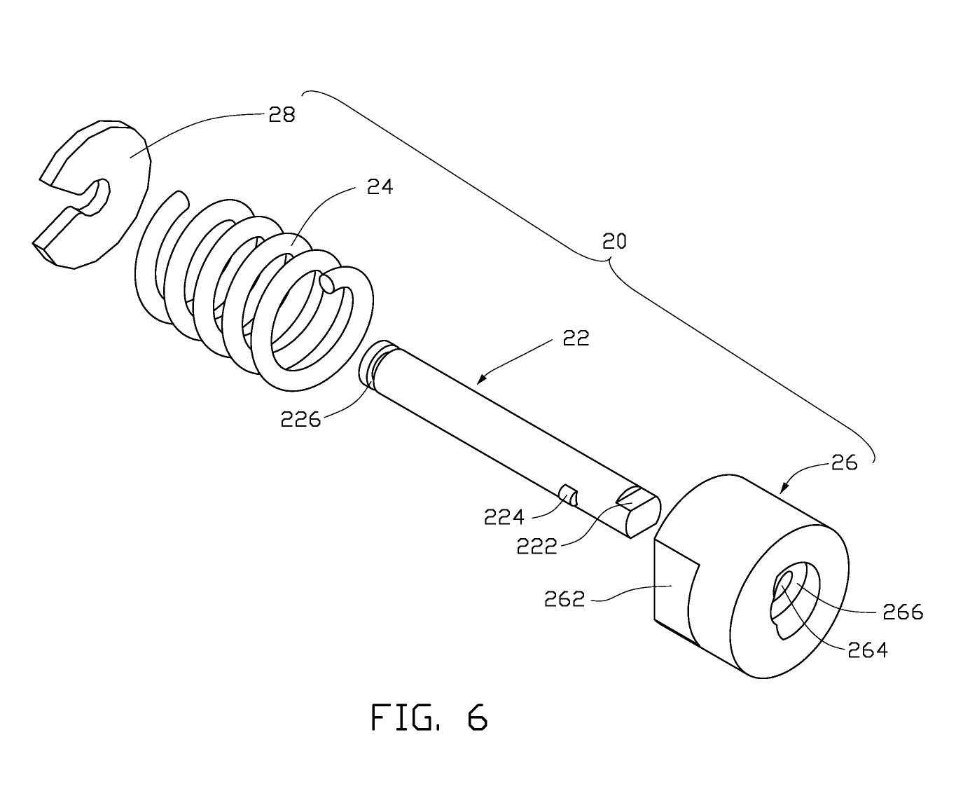

Referring to FIG. 6, a hinge assembly 20 is provided according to a second embodiment. The hinge assembly 20 includes a shaft 22, a spring 24, a follower 26, and a locking element 28. The shaft 20 includes a deformed portion 222 at one end thereof, and a loop groove 226 at the other end thereof. The deformed portion 222 of the shaft 22 is engaged in the body section 120 of the mobile phone 100, and cannot rotate relative to the body section 120. A projection 224 is formed at the shaft 12 adjacent to the deformed portion 222. The projection 224 is substantially semicircular.

The spring 24 is preferably helical and metallic, and can be located around the shaft 22. The follower 26 is generally cylindrical in shape. The follower 26 includes two opposite planar surfaces 262. The follower 26 has an inner peripheral wall and a through hole 264 extending therethrough. A screw portion 266 is formed on the inner peripheral wall corresponds to the projection 224 of the shaft 22. The screw portion 266 is a singe thread, which is a raised helical or spiral rib/ridge around a center of the through hole 264. The follower 26 may be placed around the shaft 22 by the through hole 264, with the projection 224 engaging with the screw portion 266. The locking element 28 is a C-shape ring, and is used for engaging in the loop groove 226 of the shaft 22.

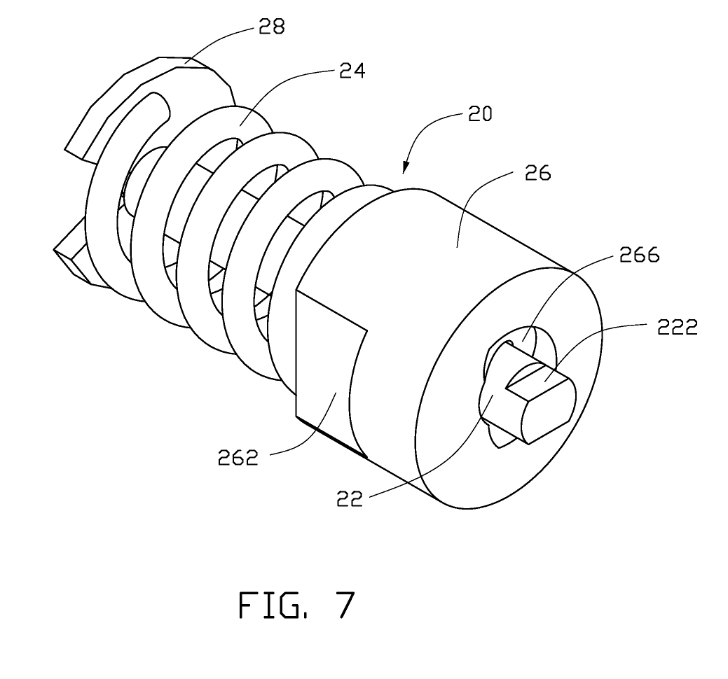

Referring to FIG. 7, in assembly, the locking element 28 is locked in the loop groove 226 of the shaft 22. The spring 24 is placed around the shaft 22 so that one end of the spring 24 resists the locking element 28. Then, the shaft 22 passes through the through hole 264 of the follower 26, and the projection 224 of the shaft 22 engages in the screw portion 266 of the follower 26. The other end of the spring 24 resists the follower 26. The spring 24 is compressed so as to accumulate a predetermined spring force. Finally, the hinge assembly 20 is assembled in the mobile phone. The assembled process of the hinge assembly 20 and the mobile phone is similar to the first embodiment, and is not detailed herein. In use, either of the follower 26 or the cover section is unlocked, the follower 26 rotates and slides relative to the shaft 22 so as to achieve the cover section to be opened relative to the body section.

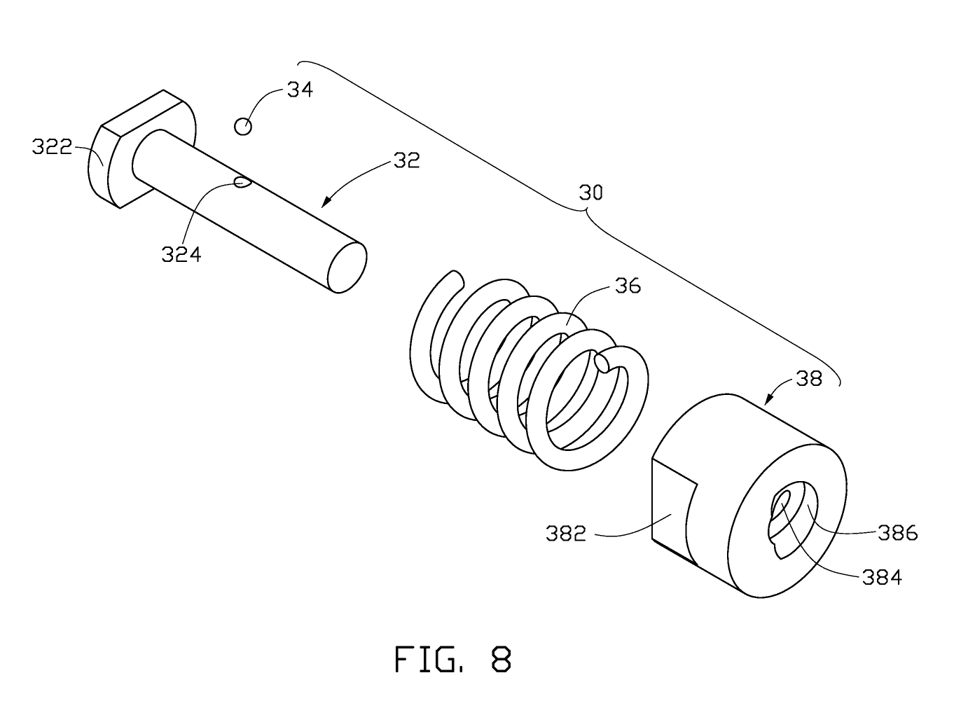

Referring to FIG. 8, a hinge assembly 30 is provided according to a present third embodiment. The hinge assembly 30 includes a shaft 32, a rolling element 34, a spring 36, and a follower 38. The shaft 30 has a flange 322 formed at one end thereof. The flange 322 is a deformed cylinder engaged in a body section of a mobile phone, and cannot rotate relative to the body section. A semicircular groove 324 is defined in a middle upper portion of the shaft 22.

The rolling element 34 is sphere-shaped made of stainless iron. A diameter of the rolling element 34 is substantially similar to that of the groove 324 so that the rolling element 34 can be received in the groove 324.

The spring 36 is preferably helical and metallic, and can be placed around the shaft 32. The follower 38 is generally cylindrical in shape. The follower 38 includes two opposite planar surfaces 382. The follower 38 has an inner peripheral wall and a through hole 384 extending therethrough. A screw portion 386 is formed on the inner peripheral wall corresponds to the rolling element 34 received in the shaft 32. The rolling element 34 may be engaged with the screw portion 386.

In assembly, the spring 36 is placed around the shaft 32. Then, the rolling element 34 is disposed in the groove 324 of the shaft 32. After that, the follower 38 is placed around the shaft 32, and the rolling element 34 of the shaft 32 engaging in the screw portion 386 of the follower 38. One end of the spring 36 resists the follower 38, the other end of the spring 36 resists the flange 322. The spring 24 is compressed so as to accumulate a predetermined spring force. The hinge assembly 30 is assembled in the mobile phone. The assembled process of the hinge assembly 30 with the mobile phone is similar to the first embodiment, and is not detailed herein. In use, either of the follower 38 or the cover section is unlocked, the follower 38 rotates and slides relative to the shaft 32 so as to realize the cover section to be opened relative to the body section.

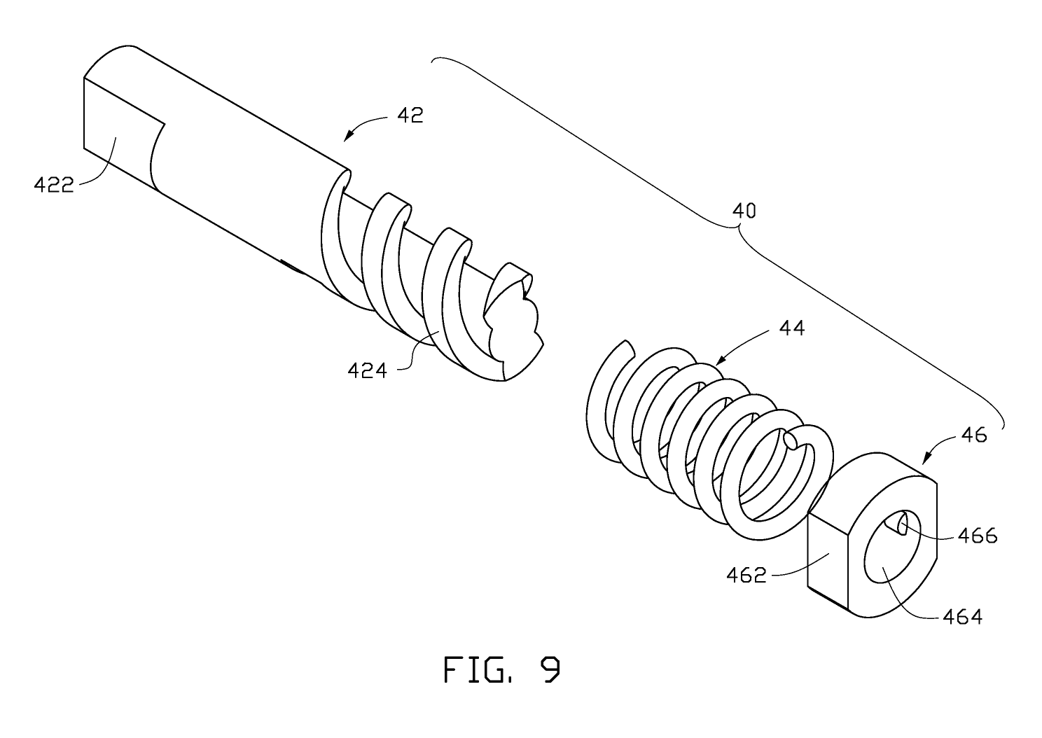

Referring now to FIG. 9, a hinge assembly 40 according to a fourth embodiment is provided. The hinge assembly 40 includes a shaft 42, a spring 44 and a follower 46.

The shaft 42 has an outer peripheral surface thereof. One end of the shaft 42 defines a screw portion 424 at the outer peripheral surface thereof, and the other end of the shaft 42 forms a deformed portion 422 functioning as a securing portion. The screw portion 424 includes two threads with two spaced raised helical or spiral rib/ridge going around the shaft 12. The spring 44 is preferably helical and metallic. The spring 44 has an inner diameter larger than a diameter of the shaft 42. Thus, the spring 44 can be placed around the shaft 42.

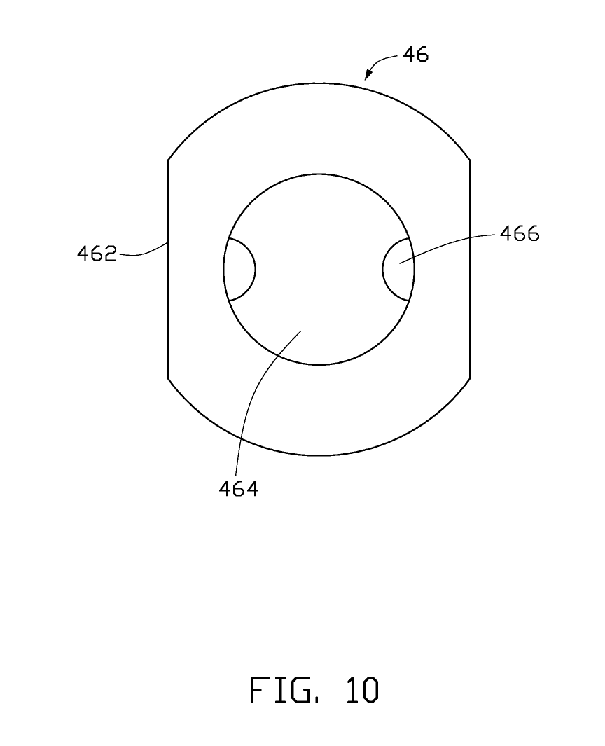

Referring now to FIG. 10, the follower 46 is generally cylindrical in shape. The follower 46 includes two opposite planar surfaces 462. The follower 46 has an inner peripheral wall and a through hole 464 extending therethrough. Two symmetrically projections 466 are formed on the inner peripheral wall corresponds to the screw portion 424 of the shaft 42. Each projection 466 is substantially a semicircular cylinder, and includes an arcuate surface toward a center of the through hole 464.

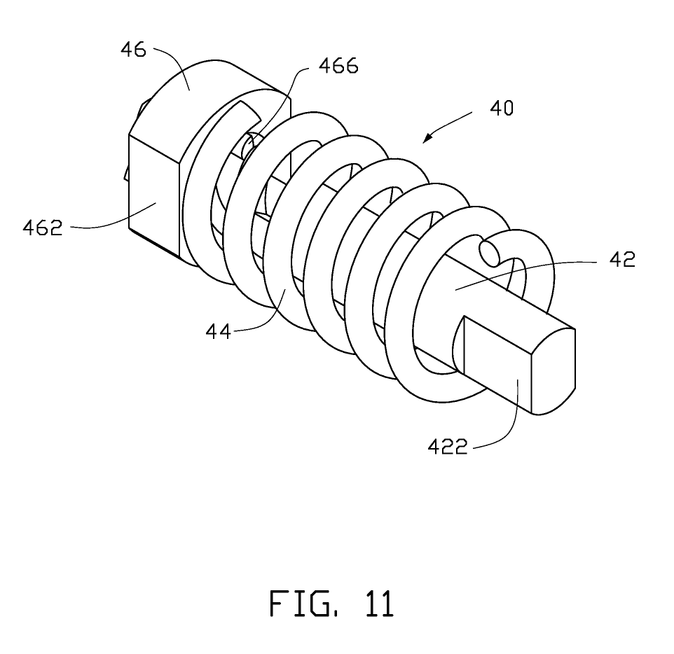

Referring to FIG. 11, in assembly, the spring 44 is placed around the shaft 42. The shaft 42 passes through the through hole 464 of the follower 46 and the projections 466 engage into the screw portion 424 of the shaft 42.

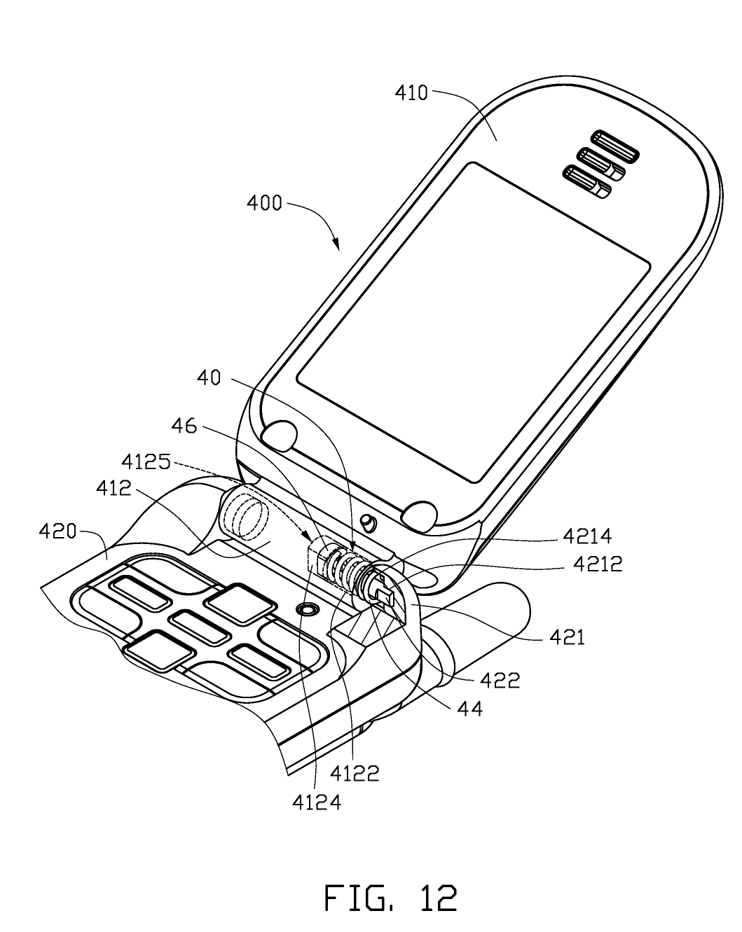

Referring to FIG. 12, the mobile phone 400 includes a cover section 410 and a body section 420. The cover section 410 has a connecting portion 412 at one end thereof. The connecting portion 412 defines a receiving cavity 4122 and a first reverse rotating groove 4124 at one end thereof. The receiving cavity 4122 is adjacent to the first reverse rotating groove 4124. The connecting portion 412 has a bottom wall 4125 adjacent to the first reverse rotating groove 4124. One end of the body section 420 has an engaging portion 421. The engaging portion 421 defines a second reverse rotating groove 4212 and a receiving groove 4214.

The hinge assembly 40 is assembled in the mobile 400, one end of the assembled hinge assembly 40 with the follower 46 is inserted into the receiving cavity 4122. The follower 46 is engaged in the first reverse rotating groove 4124 via the planar surfaces 462, and the end of the deformed portion 422 of the shaft 42 is engaged with the second reverse rotating groove 4212. One part of the spring 44 is received in the receiving groove 4214. One end of the spring 44 resist the bottom wall 4125 of the receiving groove 4214, the other end resists the follower 46.

Understandably, the thread number of the shaft may be more than two. Accordingly, the number of the projection in the follower corresponds to the thread number. If the thread of the screw portion is a single thread, the projection of the follower may be disposed two. The axial and radial distance between the projections, beneficially, corresponds to the thread distance of the shaft so that the two projections may engage in the thread of the shaft.

In further alternative embodiments, the spring can be made of a nonmetallic material such as plastic. Furthermore, the spring can instead be made of other kind of elastic element or driving structure such as a resilient cylinder. Understandably, a diameter of the spring may be smaller than that of the shaft. Accordingly, the spring does not place around the shaft, instead, the spring directly resists one end of the shaft for providing a force allowing the follower to move relative to the shaft. Alternatively, the spring may be omitted, and an axial push force is provided for the shaft or the follower so that the shaft and the follower move relative to each other.

The deformed portion of the shaft may be replaced with other configuration securing portion. In addition, the planner faces of the follower may be replaced with other configuration structure.

Alternatively, the groove of the rolling element may be not semicircular, and the groove may be half-cylindrical as long as the rolling element is received in the groove and not rotate along a peripheral direction. In addition, the groove may be a helical thread.

Alternatively, the shape of the projection or the rolling element is not limited as functioning a resisting portion for resisting the thread to realize the movement between the shaft and the follower. In addition, the spring may be not limited to resist the body section, and may resist the cover section.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A hinge assembly comprising:
a shaft and a follower, wherein one of the shaft and the follower define a screw portion, the other of the shaft and the follower disposes at least one resisting portion, and the shaft and the follower slide and rotate relative to each other.

2. The hinge assembly as claimed in claim 1, further comprising an elastic element, the elastic element providing a force allowing the shaft to move relative to the follower.

3. The hinge assembly as claimed in claim 1, wherein the shaft defines the screw portion, the follower has a through hole which is surrounded by an inner peripheral wall thereof, and the at least one resisting portion extending from the inner peripheral wall for engaging with the screw portion of the shaft.

4. The hinge assembly as claimed in claim 1, wherein the shaft defines a groove, the resisting portion being a rolling element, the rolling element being received in the groove, the follower defining a through hole which is surrounded by an inner circumferential wall, the screw portion being defined on the inner circumferential wall for engaging with the rolling element.

5. The hinge assembly as claimed in claim 1, wherein the resisting portion is disposed in the shaft, the follower has a through hole which is surrounded by an inner circumferential wall, and the screw portion is defined on the inner circumferential wall for engaging with the resisting portion.

6. The hinge assembly as claimed in claim 1, wherein one end of the shaft forms a securing portion, the securing portion being a deformed cylinder, and the follower being a cylinder with two planner surfaces.

7. The hinge assembly as claimed in claim 2, wherein one end of the shaft forms a locking element, the elastic element being placed around the shaft, and one end of the elastic element resisting the follower, and the other end of the elastic element resisting the locking element.

8. The hinge assembly as claimed in claim 7, wherein the locking element is a C-shape ring, one end of the shaft defining a loop groove, and the ring being locked into the loop groove of the shaft.

9. The hinge assembly as claimed in claim 7, wherein the securing element is a flange integrally formed with the shaft, and the flange is a deformed cylinder.

10. The hinge assembly as claimed in claim 2, wherein the shaft defines a pin hole, one end of the elastic element is fixed in the pin hole, and the other end of the elastic element resists the follower.

11. The hinge assembly as claimed in claim 2, wherein the elastic element resists one end of the shaft.

12. The hinge assembly as claimed in claim 1, wherein the screw portion has a thread, and a thread lead angle of the thread is larger than a friction angle.

13. The hinge assembly as claimed in claim 1, wherein the screw portion is disposed on the shaft, the screw portion includes two threads, the follower has a through hole which is surrounded by an inner circumferential wall, the inner circumferential wall forms two resisting portion, and each resisting portion engages with a corresponding thread of the shaft.

14. A foldable electronic device having at least two components hinged together by a hinge assembly, the hinge assembly comprising:
a shaft and a follower, wherein one of the shaft and the follower define a screw portion, the other of the shaft and the follower dispose at least one resisting portion, and the shaft and the follower slide and rotate relative to each other.

15. The foldable electronic device as claimed in claim 14, wherein the hinge assembly further comprises an elastic element, the elastic element providing a force allowing the shaft to move relative to the follower.

16. The foldable electronic device as claimed in claim 14, wherein the shaft defines a thread, the follower defines a through hole which is surrounded by an inner peripheral wall thereof, the at least one resisting portion is formed on the inner peripheral wall, the at least one resisting portion is a projection for engaging with the thread of the shaft.

17. The foldable electronic device as claimed in claim 14, wherein the shaft defines a groove, the resisting portion is a rolling element, the rolling element is received in the groove, the follower has a through hole which is surrounded by an inner circumferential wall, and the inner circumferential wall defines the screw portion for engaging with the rolling element.

18. The foldable electronic device as claimed in claim 14, wherein the resisting portion is disposed in the shaft, the follower has a through hole which is surrounded by an inner circumferential wall, and the inner circumferential wall defines the screw portion for engaging with the resisting portion.

19. The foldable electronic device as claimed in claim 14, wherein the screw portion is formed on the shaft, the screw portion includes two threads, the follower has a through hole which is surrounded by an inner circumferential wall, the inner circumferential wall forms two resisting portions, and each resisting portion engages with a corresponding thread of the shaft.

20. The foldable electronic device as claimed in claim 15, wherein the elastic element is placed around the shaft, one end of the elastic element resists the follower, the other end of the elastic element resists one of two components.
